(19) United States
(12) Patent Application Publication
(10) Pub. No.: US 2010/0097770 A1
(43) Pub. Date: Apr. 22, 2010

(54) PRINTED CIRCUIT BOARD AND MANUFACTURING METHOD THEREOF

(75) Inventors: Hwa-Sun Park, Suwon-si (KR); Yul-Kyo Chung, Yongin-si (KR); Jong-Man Kim, Yongin-si (KR); One-Cheol Bae, Pyeongtaek-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/406,636

(22) Filed: Mar. 18, 2009

(30) Foreign Application Priority Data
Oct. 20, 2008 (KR) 10-2008-0102508

(51) Int. Cl. H05K 1/16; H05K 3/46; H05K 3/00; H05K 1/00

(52) U.S. Cl. 361/748; 216/17; 156/250; 174/260

(57) ABSTRACT

Disclosed are a printed circuit board and a manufacturing method thereof. The manufacturing method of a printed circuit board includes: mounting an electronic device on an upper surface of an adhesive layer; laminating an insulator on an upper side of the electronic device and a lower side of the adhesive layer, respectively, such that the electronic device is buried; and forming a circuit pattern and a via on the insulator.

### CROSS-REFERENCE TO RELATED APPLICATIONS

This application claims the benefit of Korean Patent Application No. 10-2008-0102508, filed with the Korean Intellectual Property Office on Oct. 20, 2008, the disclosure of which is incorporated herein by reference in its entirety.

### BACKGROUND

1. Technical Field

The present invention relates to a printed circuit board and a manufacturing method thereof.

2. Description of the Related Art

In today's rapidly changing advanced information, there is an increasing demand for multi-functional, smaller active devices, which used to be surface-mounted, in order to provide more functions in a smaller space. By embedding an IC, which used to be mounted in the form of a package or a direct-chip-attach on an existing substrate, in an organic substrate, an embedded IC can secure extra surface area and realize multi functions.

Moreover, it is also possible to form a kind of next generation three-dimensional package technology, that can meet the expectation for a high frequency low-loss/high-efficiency technology and reduction of size by minimizing the number of signal transmission lines, and to lead a trend for a new type of high-performance packaging.

More specifically, if a chip that used to be mounted on the surface is embedded, there will be an extra surface space on the surface to add more functions as long as the module size and thickness are unchanged. Additionally, the length of chip-to-chip interconnection can be optimized, and the wiring between the chip and a main substrate can be made as short as possible. Moreover, high frequency through ESL can be optimally designed, and EMI can be minimized. Furthermore, the space for wire bonding can be saved. If a stacked chip is directly embedded, the memory capacity can be increased by at least twice.

Currently, various methods of embedding an active device in a core substrate are being developed.

### SUMMARY

The present invention provides a method of manufacturing a printed circuit board embedded with an electronic device that is capable of improving the production yield by simplifying a process.

An aspect of the present invention features a method of manufacturing a printed circuit board. The method in accordance with an embodiment of the present invention includes: mounting an electronic device on an upper surface of an adhesive layer; laminating an insulator on an upper side of the electronic device and a lower side of the adhesive layer, respectively, such that the electronic device is buried; and forming a circuit pattern and a via on the insulator.

The laminating of the insulator can be performed at the same time for both the upper side of the electronic device and the lower side of the adhesive layer.

Meanwhile, before the mounting of the electronic device, the method can further perform laminating a core substrate having a cavity formed therein on an upper surface of the adhesive layer. Here, the electronic device can be mounted on the adhesive layer through the cavity.

When there are a plurality of the electronic devices, some of the plurality of electronic devices can be arranged such that an electrode faces upward and the rest of the electronic devices can be arranged such that an electrode faces downward. Here, the some of the plurality of electronic devices can be mounted on an upper surface of the adhesive layer and the rest of the electronic devices can be mounted on a lower surface of the adhesive layer.

An alignment mark for aligning the electronic device can be formed on the adhesive layer. The alignment mark can be a hole extended through the adhesive layer.

Another aspect of the present invention features a manufacturing method of a printed circuit board. The method in accordance with an embodiment of the present invention includes: an adhesive layer; an electronic device mounted on the adhesive layer; a substrate unit laminated on an upper surface and a lower surface of the adhesive layer such that the electronic device is buried; and a circuit pattern and a via being formed on the substrate unit.

The substrate unit can include: a core substrate laminated on the upper surface of the adhesive layer, a cavity being formed in the core substrate such that the electronic device is embedded; and an insulator laminated on an upper surface of the core substrate and on the lower surface of the adhesive layer.

When there a plurality of the electronic devices; and some of the plurality of electronic devices can be arranged such that an electrode faces upward and the rest of the electronic devices can be arranged such that an electrode faces downward. Here, the some of the plurality of electronic devices can be mounted on the upper surface of the adhesive layer and the rest of the electronic devices can be mounted on the lower surface of the adhesive layer.

An alignment mark for aligning the electronic device can be formed on the adhesive layer. The alignment mark can be a hole extended through the adhesive layer.

### BRIEF DESCRIPTION OF THE DRAWINGS

FIG. 1 is a flowchart showing a manufacturing method of a printed circuit board according to an embodiment of the present invention.

FIGS. 2 through 7 show each respective process of a manufacturing method of a printed circuit board according to an embodiment of the present invention.

FIG. 8 is a flowchart showing a manufacturing method of a printed circuit board according to another embodiment of the present invention.

FIGS. 9 through 15 show each respective process of a manufacturing method of a printed circuit board according to another embodiment of the present invention.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the spirit and scope of the present invention. Throughout the description of the present invention, when describing a certain technology is determined to evade the point of the present invention, the pertinent detailed description will be omitted.

Hereinafter, some embodiments of a printed circuit board and a manufacturing method thereof in accordance with the present invention will be described in detail with reference to the accompanying drawings. In description with reference to the accompanying drawings, the same reference numerals will be assigned to the same or corresponding elements, and any redundant description thereof will be omitted.

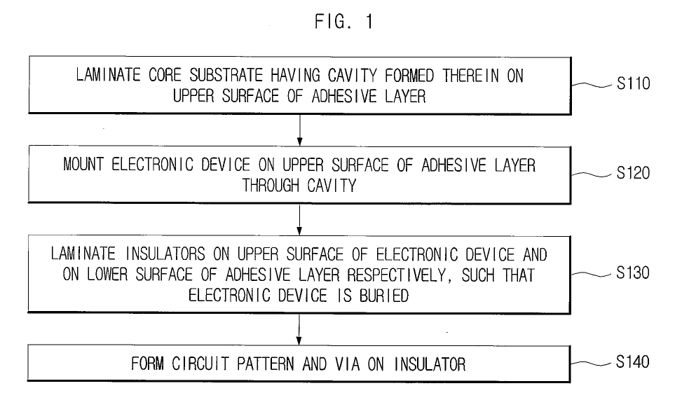

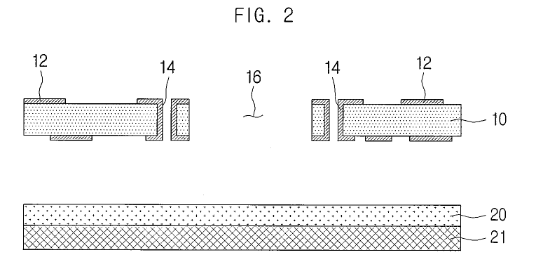

First, a manufacturing method of a printed circuit board according to an embodiment of the present invention will be described. FIG. 1 is a flowchart showing a manufacturing method of a printed circuit board according to an embodiment of the present invention. FIGS. 2 through 7 show each respective process of the manufacturing method of a printed circuit board according to an embodiment of the present invention. Shown in FIGS. 2 through 7 are a core substrate 10, circuit patterns 12 and 45, vias 14 and 46, a cavity 16, an adhesive layer 20, release paper 21, an electronic device 30, an electrode 32, insulators 41 and 43, and base substrates 42 and 44.

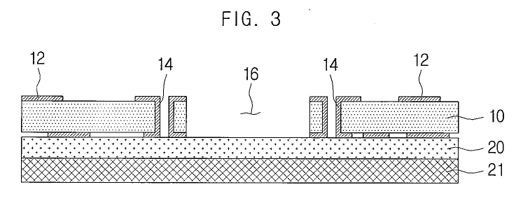

As shown in FIGS. 2 and 3, the core substrate 10 having the cavity 16 formed therein is laminated on the upper surface of the adhesive layer 20 (S110). The core substrate 10 can be made of glass-fiber-reinforced resin and the like. The central part of the core substrate 10 can have the cavity 16 formed therein for embedding the electronic device 30. The cavity 16 can be formed by various methods, including, for example, a mechanical drilling process and a chemical etching process.

Meanwhile, as shown in FIG. 2, the via 14 and various kinds of circuit patterns 12, etc., can be formed in the core substrate 10 in order to make an electrical connection between layers. The lower surface of the adhesive layer 20 can be covered with the release paper 21.

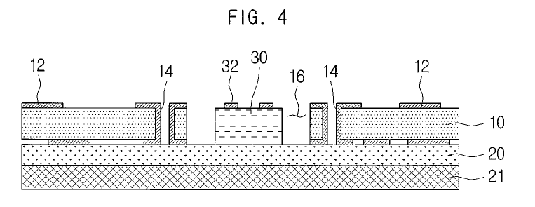

Then, as shown in FIG. 4, the electronic device 30 is mounted on the upper surface of the adhesive layer 20 through the cavity 16 (S120). That is, the electronic device 30 is mounted on the upper surface of the adhesive layer 20, which is exposed through the cavity 16. In this case, the electrode 32 being formed on one surface of the electronic device 30 can face upward or, if necessary, face downward.

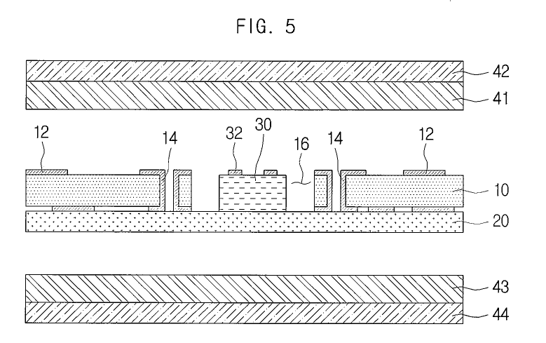

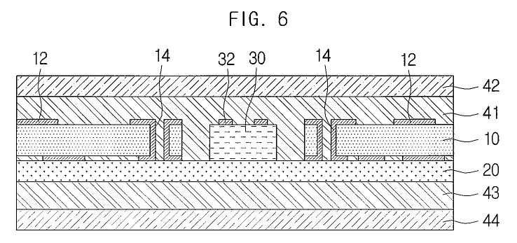

Then, after removing the release paper formed on the lower surface of the adhesive layer, the insulators 41 and 43 are, as shown in FIGS. 5 and 6, laminated on the upper surface of the electronic device 30 and on the lower surface of the adhesive layer 20, respectively, such that the electronic device 30 is buried (S130). In other words, the insulators 41 and 43 are laminated without removing the adhesive layer 20. As such, subsequent processes are performed without removing the adhesive layer 20, eliminating unnecessary processes caused by removing the adhesive layer 20 and thus improving the production yield.

For example, in the case of removing the adhesive layer, it was required that the electronic device 30 was fixed by laminating the insulator on the upper surface of the electronic device 30 and then the adhesive layer was removed before the insulator was laminated again on the lower surface of the electronic device 30.

However, according to the embodiment of the present invention, the process of removing the adhesive layer 20 can be omitted because the adhesive layer 20 is not removed, and the processes of laminating the insulators 41 and 43 on the upper side and lower side of the electronic device 30 can be performed at the same time, making it possible to reduce the time required to laminate the insulators 41 and 43.

Prepreg in a semi-cured state (B-stage), etc., can be used as the insulators 41 and 43. It shall be evident that various other materials can be also used as the insulator as necessary. In order to make it easier to laminate the insulators, the insulators 41 and 43 can be supported by the base substrates 42 and 44, as shown in FIG. 5.

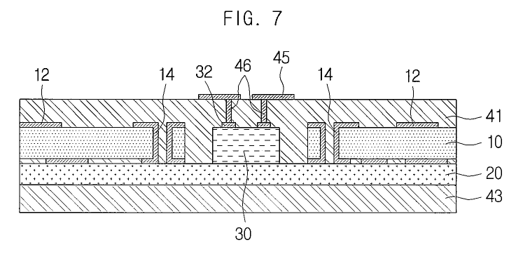

Then, after removing the base substrates 42 and 44, the circuit pattern 45 and the via 46 are formed on the insulator 41 (S140). Methods such as electroless plating and electrolytic plating can be used so as to form the circuit pattern 45 and the via 46. While FIG. 7 shows that the circuit pattern 45 and the via 46 have been formed only on the insulator 41 laminated on the electronic device 30, the circuit pattern and the via can be also formed on the insulator 43 laminated on the lower side of the electronic device 30.

FIG. 7 show a printed circuit board that has been manufactured through the process described above. Such a printed circuit board has a structure in which the electronic device 30 is mounted on the adhesive layer 20 and a substrate unit is laminated on the upper and lower surfaces of the adhesive layer 20 such that the electronic device 30 is buried. In the embodiment shown in FIG. 7, the substrate unit includes the core substrate 10 and the insulators 41 and 43.

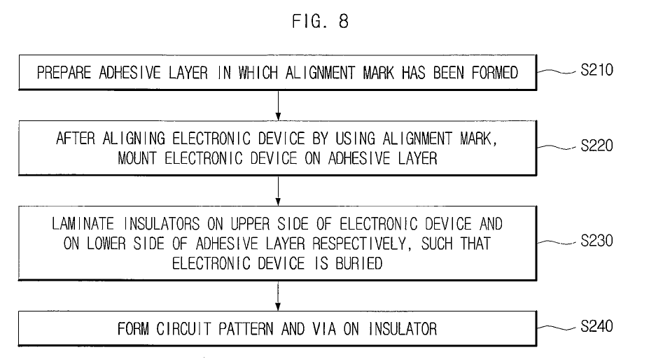

Next, a manufacturing method of a printed circuit board according to another embodiment of the present invention will be described with reference to FIGS. 8 through 15. Compared with the embodiment of the present invention described earlier, the manufacturing method according to another embodiment of the present invention does not use the core substrate 10 separately and aligns electronic devices 30, 30a and 30b by forming an alignment mark 22 on the adhesive layer 20.

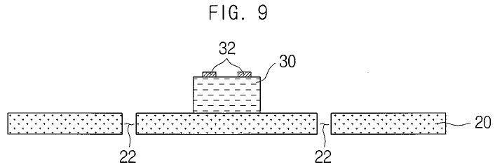

FIG. 8 is a flowchart showing a manufacturing method of a printed circuit board according to another embodiment of the present invention. FIGS. 9 through 15 show each respective process of a manufacturing method of a printed circuit board according to another embodiment of the present invention. Shown in FIGS. 9 through 15 are a circuit patterns 45, a via 46, 46a, 46b and 47, an adhesive layer 20, an alignment mark 22, electronic devices 30, 30a and 30b, electrodes 32, 32a and 32b, and insulators 41 and 43.

First, the adhesive layer 20 in which an alignment mark 22 is formed is prepared (S210). After aligning the electronic device 30 by use of the alignment mark 22, the electronic device 30 is mounted on the adhesive layer 20 (S220, see FIG. 9). A hole extended through the adhesive layer 20 can be used as the alignment mark 22 being formed on the adhesive layer 20. That is, a method of boring a hole through the adhesive layer 20 can be used in order to form the alignment mark 22. It shall be evident that, in addition to a hole shape, various shapes of alignment marks can be also used.

By mounting the electronic device 30 on the adhesive layer 20 after aligning the electronic device 30 by using the alignment mark 22 as described above, the manufacturing error that may occur in subsequent processes can be minimized.

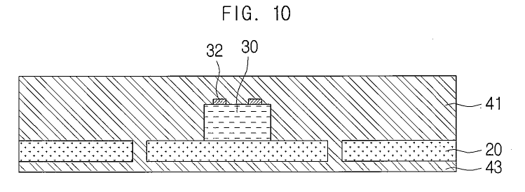

Then, the insulators 41 and 43 are laminated, as shown in FIG. 10, on the upper side of the electronic device 30 and on the lower side of the adhesive layer 20, respectively, such that the electronic device 30 is buried (S230). In other words, similarly to the embodiment described earlier, the insulators 41 and 43 are laminated without removing the adhesive layer 20. As such, subsequent processes are performed without removing the adhesive layer 20, eliminating unnecessary processes associated with the removing of the adhesive layer 20 and thus improving the production yield.

Prepreg in a semi-cured state (B-stage), etc., can be used as the insulators 41 and 43. It shall be evident that various other materials can be also used as the insulator as necessary.

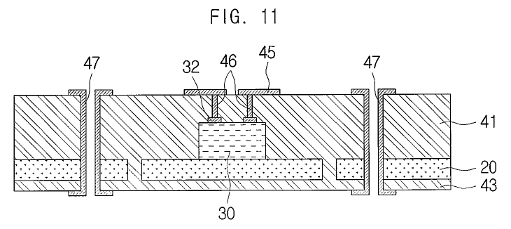

As shown in FIG. 11, the circuit pattern 45 and the via 46 are formed on the insulators 41 and 43 (S240). As described above, methods such as electroless plating and electrolytic plating can be used so as to form the circuit pattern 45 and the via 46.

FIG. 11 show a printed circuit board that has been manufactured through the process described above. Such a printed circuit board has a structure in which the electronic device 30 is mounted on the adhesive layer 20 and a substrate unit is laminated on the upper and lower surfaces of the adhesive layer 20 such that the electronic device 30 is buried. In the embodiment shown in FIG. 11, the substrate unit includes the insulators 41 and 43.

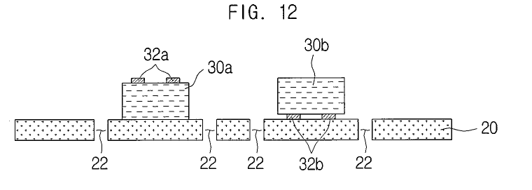

Meanwhile, a plurality of the electronic devices can be mounted, as shown in FIG. 12. While FIG. 12 shows that two electronic devices 30a and 30b are mounted on the adhesive layer 20, it shall be evident that three or more electronic devices can be also mounted.

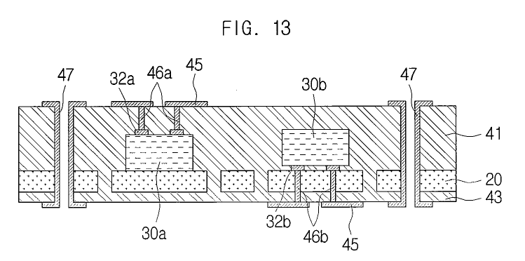

When a plurality of electronic devices 30a and 30b are mounted on the adhesive layer 20 as described above, some electronic devices can be arranged such that the electrodes 32a face upward and other electronic devices can be arranged such that the electrodes 32b face downward. Through this structure, both sides of the printed circuit board can be efficiently utilized, as shown in FIG. 13.

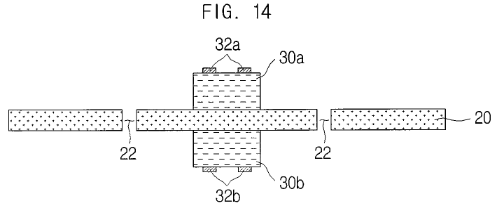

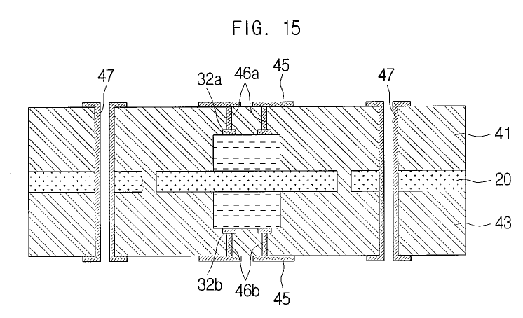

Moreover, as shown in FIG. 14, some electronic devices can be mounted on the upper surface of the adhesive layer 20 such that the electrodes 32a face upward and other electronic devices can be mounted on the lower surface of the adhesive layer 20 such that the electrodes 32b face downward. In this case as well, as shown in FIG. 15, both sides of the printed circuit board can be efficiently utilized.

While the present invention has been described with reference to certain embodiments thereof, it will be understood by those skilled in the art that various changes and modification in forms and details can be made without departing from the spirit and scope of the present invention as defined by the appended claims.

Numerous embodiments other than the embodiments described above are included within the scope of the present invention.

What is claimed is:

1. A method of manufacturing a printed circuit board, comprising:
mounting an electronic device on an upper surface of an adhesive layer;
laminating an insulator on an upper side of the electronic device and a lower side of the adhesive layer, respectively, such that the electronic device is buried; and
forming a circuit pattern and a via on the insulator.

2. The method of claim 1, wherein the laminating of the insulator is performed at the same time for both the upper side of the electronic device and the lower side of the adhesive layer.

3. The method of claim 1, further comprising, before the mounting of the electronic device, laminating a core substrate having a cavity formed therein on an upper surface of the adhesive layer, wherein the electronic device is mounted on the adhesive layer through the cavity.

4. The method of claim 1, wherein:
there are a plurality of the electronic devices; and
some of the plurality of electronic devices are arranged such that an electrode faces upward and the rest of the electronic devices are arranged such that an electrode faces downward.

5. The method of claim 4, wherein the some of the plurality of electronic devices are mounted on an upper surface of the adhesive layer and the rest of the electronic devices are mounted on a lower surface of the adhesive layer.

6. The method of claim 1, wherein an alignment mark for aligning the electronic device is formed on the adhesive layer.

7. The method of claim 6, wherein the alignment mark is a hole extended through the adhesive layer.

8. A printed circuit board comprising:
an adhesive layer;
an electronic device mounted on the adhesive layer;
a substrate unit laminated on an upper surface and a lower surface of the adhesive layer such that the electronic device is buried; and
a circuit pattern and a via being formed on the substrate unit.

9. The printed circuit board of claim 8, wherein the substrate unit comprises:
a core substrate laminated on the upper surface of the adhesive layer, a cavity being formed in the core substrate such that the electronic device is embedded; and
an insulator laminated on an upper surface of the core substrate and on the lower surface of the adhesive layer.

10. The printed circuit board of claim 8, wherein:
there are a plurality of the electronic devices; and
some of the plurality of electronic devices are arranged such that an electrode faces upward and the rest of the electronic devices are arranged such that an electrode faces downward.

11. The printed circuit board of claim 10, wherein the some of the plurality of electronic devices are mounted on the upper surface of the adhesive layer and the rest of the electronic devices are mounted on the lower surface of the adhesive layer.

12. The printed circuit board of claim 8, wherein an alignment mark for aligning the electronic device is formed on the adhesive layer.

13. The printed circuit board of claim 12, wherein the alignment mark is a hole extended through the adhesive layer.
